(19) United States
(12) Patent Application Publication
(10) Pub. No.: US 2023/0020495 A1
(43) Pub. Date: Jan. 19, 2023

(54) LOAD-MODULATED PUSH-PULL POWER AMPLIFIER

(71) Applicant: Skyworks Solutions, Inc., Irvine, CA (US)

(72) Inventors: Philip John Lehtola, CEDAR RAPIDS, IA (US); Bo Pan, Irvine, CA (US)

(21) Appl. No.: 17/811,916

(22) Filed: Jul. 12, 2022

Related U.S. Application Data
(60) Provisional application No. 63/221,085, filed on Jul. 13, 2021.

(51) Int. Cl. H03F 3/21

(52) U.S. Cl. CPC H03F 3/21; H03F 2200/09; H03F 2200/451; H03F 2200/294

(57) ABSTRACT

Aspects of the disclosure include a power amplifier comprising an input to receive an input signal, an output to provide an amplified output signal, a balun coupled between the input and the output, at least one capacitor coupled to the balun, and a controllable load coupled to the at least one capacitor.

### CROSS-REFERENCE TO RELATED APPLICATIONS

This application claims priority under 35 U.S.C. § 119(e) to U.S. Provisional Application Ser. No. 63/221,085, titled “LOAD MODULATED PUSH PULL POWER AMPLIFIER,” filed on Jul. 13, 2021, which is hereby incorporated by reference in its entirety.

### BACKGROUND

### 1. Field of the Disclosure

At least one example in accordance with the present disclosure relates generally to power amplifiers.

### 2. Discussion of Related Art

Electronic devices, such as mobile cellular devices, may exchange information with other electronic devices. A mobile cellular device may include an antenna to transmit and receive signals. Mobile cellular devices may include additional components and circuitry to process signals transmitted and received via the antenna. For example, a mobile cellular device may include one or more power amplifiers to amplify a signal transmitted or received via the antenna.

### SUMMARY

According to at least one aspect of the present disclosure, a power amplifier is provided comprising an input to receive an input signal, an output to provide an amplified output signal, a balun coupled between the input and the output, at least one capacitor coupled to the balun, and a controllable load coupled to the at least one capacitor and being configured to present, with the at least one capacitor, a variable impedance to the balun.

In various examples, the controllable load includes a switch. In at least one example, the switch includes a heterojunction bipolar transistor. In some examples, the power amplifier includes an input split configured to transform the input signal to a balanced signal, an input driver coupled between the input and the input split, and an output driver coupled between the input driver and the balun. In various examples, the power amplifier includes an interstage match between the input driver and the output driver configured such that a collector impedance of the input driver is out-of-phase with a collector impedance of the output driver.

In at least one example, increasing the controllable load increases a gain and a saturation power of the power amplifier. In some examples, increasing the controllable load increases the collector impedance of the input driver and decreases a collector impedance of the output driver. In various examples, the controllable load is a variable resistance. In at least one example, the input driver includes a cascode amplifier. In some examples, the input driver includes a common-emitter amplifier. In various examples, the output driver includes a common-emitter amplifier. In at least one example, the controllable load is a variable resistance.

According to at least one aspect of the disclosure, a method of controlling a power amplifier is provided comprising providing a power amplifier having a balun, at least one capacitor coupled to the balun, and a controllable load coupled to the at least one capacitor, and varying the controllable load to improve an efficiency of the balun.

In at least one example, the controllable load includes a switch, and varying the controllable load includes varying a control signal provided to a control connection of the switch. In some examples, the controllable load includes a variable resistor, and varying the controllable load includes varying a resistance of the variable resistor. In various examples, the power amplifier further includes an input driver and an output driver, and the method further includes implementing an interstage match between the input driver and the output driver such that a collector impedance of the input driver is out-of-phase with a collector impedance of the output driver. In at least one example, increasing the controllable load increases the collector impedance of the input driver and decreases a collector impedance of the output driver. In some examples, increasing the controllable load includes increasing a resistance of the controllable load.

According to at least one aspect of the disclosure, a power-amplifier system is provided comprising an input to receive an input signal, an output to provide an amplified output signal, a balun coupled between the input and the output, at least one capacitor coupled to the balun, and means for varying a load coupled to the at least one capacitor.

In at least one example, the power-amplifier system includes means for simultaneously increasing a gain of the power-amplifier system and a saturated power point of the power-amplifier system.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a wireless device according to an example;

FIG. 2 illustrates a block diagram of a power amplifier according to an example;

FIG. 3 illustrates a high-level schematic diagram of the power amplifier of FIG. 2 according to an example;

FIG. 4 illustrates a block diagram of a power amplifier according to another example;

FIG. 5 illustrates a schematic diagram of a load modulator coupled to a capacitor according to an example;

FIG. 6 illustrates a schematic diagram of the power amplifier of FIG. 4 according to an example;

FIG. 7 illustrates graphs depicting the effects of modulating a control signal provided to components of the power amplifier of FIG. 4 according to an example;

FIG. 8 illustrates a graph depicting a highest gain of the power amplifier of FIG. 4 for a given value of output power;

FIG. 9 illustrates a block diagram of a power amplifier according to another example;

FIG. 10 illustrates a schematic diagram of the power amplifier of FIG. 9 according to an example;

FIG. 11 illustrates Smith charts corresponding to components of the power amplifier of FIG. 9 according to an example;

FIG. 12 illustrates graphs indicative of respective performances of the power amplifier of FIG. 9 at various control-signal values according to an example;

FIG. 13 illustrates graphs indicative of overall performance of the power amplifier of FIG. 9 for a varied control signal according to an example; and

FIG. 14 illustrates a schematic diagram of the power amplifier of FIG. 9 according to an example.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Electrical devices may include power amplifiers. Power amplifiers receive an input signal, amplify the input signal based on a gain value, and output an amplified output signal based on the input signal and the gain value. Performance of a power amplifier is characterized by various metrics. Example performance metrics may include change in output amplitude per change in input amplitude (AMAM) performance, which may indicate how close a power amplifier gain is to 1 dB/dB, and efficiency, such as power-added efficiency (PAE).

In some examples, a power amplifier that is considered “ideal” may exhibit a gain that is constant, that is, does not vary as a magnitude of input power is varied. In this example, the gain may be considered perfectly linear, because it is constant. Non-ideal power amplifiers may exhibit a gain that is not linear. For example, the gain of a non-ideal power amplifier may decrease rapidly at or above a certain input-power magnitude referred to as a saturated power (PSAT). A power amplifier that has a substantially linear gain at or within a certain operating point or range may be considered to exhibit a favorable AMAM performance. Accordingly, AMAM performance is one metric of power-amplifier performance.

Non-ideal power amplifiers may not be perfectly efficient due to unintended losses in the power amplifier. For example, some power amplifiers, such as push-pull power amplifiers, may include transformers, such as baluns. A balun may have a leakage inductance. The leakage inductance may introduce inefficiencies in the balun. The power amplifier may include a filter to mitigate or eliminate the inefficiencies in the balun. For example, the power amplifier may include one or more capacitors configured to balance the leakage inductance of the balun. Balancing the leakage inductance may include mitigating or eliminating the losses in the leakage inductance. Accordingly, efficiency is another metric of power-amplifier performance.

Examples provided herein improve an AMAM performance and/or efficiency in power amplifiers, such as push-pull power amplifiers. In one example, at least one capacitor is coupled to a balun to balance a leakage inductance of the balun. The at least one capacitor may be coupled to a switch having a variable-voltage control signal. Varying the control signal may advantageously enable modulation of power-amplifier characteristics such as gain and efficiency.

In some examples, the power amplifier further includes a driver stage to improve an AMAM performance of the power amplifier. The driver stage may be coupled to a final stage (or “output stage”) configured to drive the balun. An interstage matching between the driver stage and the final stage may adjust a phase between the driver stage and the final stage to be out of phase with one another. At least because of the phase difference, increasing the variable-voltage control signal may cause a base impedance of the driver stage to increase as a collector impedance of the final stage decreases, and vice versa. This out-of-phase relationship may advantageously cause a gain of the power amplifier to increase as a PSAT increases. An AMAM performance of the power amplifier may thus be increased by the impedances varying in opposite directions.

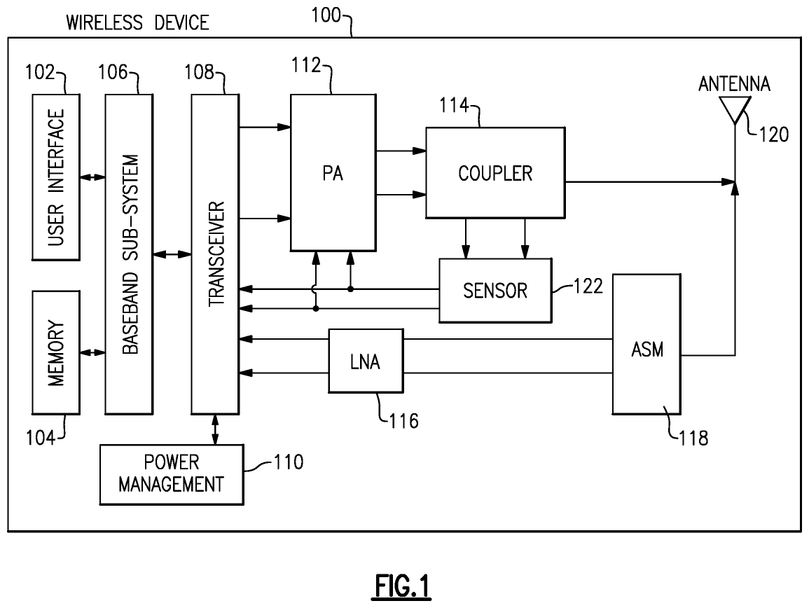

Example power amplifiers may be implemented according to various configurations. For purposes of explanation only, examples are given with respect to push-pull power amplifiers. However, it is to be appreciated that the principles of the disclosure are not limited to push-pull power amplifiers. Furthermore, power amplifiers according to the disclosure may be implemented in any of a variety of electronic devices, such as consumer electronics, automobiles, appliances, laptop computers, desktop computers, industrial equipment, and so forth. For purposes of explanation only, examples may be provided in which power amplifiers are implemented in wireless cellular devices, such as smartphones. For example, an example power amplifier may be implemented in a wireless device as discussed below with respect to FIG. 1.

FIG. 1 illustrates a block diagram of a wireless device 100 according to an example. The wireless device 100 can be a cellular phone, smart phone, tablet, modem, communication network or any other portable or non-portable device configured for voice and/or data communication. The wireless device 100 includes a user interface 102, memory and/or storage 104, a baseband sub-system 106, a transceiver 108, a power-management system 110, a power-amplifier (PA) module 112, a coupler 114, a low-noise amplifier (LNA) 116, a switching circuit 118 (also referred to as an antenna switch module [ASM]), an antenna 120, and at least one sensor 122.

The antenna 120 is configured to transmit and/or receive one or more signals, such that the wireless device 100 may communicate with one or more external devices via the antenna 120. The transceiver 108 is configured to generate signals for transmission and/or to process received signals. In some embodiments, transmission and reception functionalities can be implemented in separate components (for example, a transmit module and a receiving module) or be implemented in the same module.

Signals generated for transmission are provided from the transceiver 108 to the PA module 112, which amplifies the generated signals from the transceiver 108. As will be appreciated by those skilled in the art, the PA module 112 can include one or more power amplifiers. The PA module 112 can be used to amplify a wide variety of radio-frequency (RF) or other frequency-band transmission signals. For example, the PA module 112 can receive an enable signal that can be used to pulse the output of the power amplifier to aid in transmitting a wireless local-area-network (WLAN) signal or any other suitable pulsed signal. The PA module 112 can be configured to amplify any of a variety of types of signal, including, for example, a 5G signal, a Global System for Mobile (GSM) signal, a code-division multiple-access (CDMA) signal, a W-CDMA signal, a Long-Term-Evolution (LTE) signal, or an EDGE signal. In certain embodiments, the PA module 112 and associated components including switches and the like can be fabricated on GaAs substrates using, for example, pHEMT or BiFET transistors, or on a silicon substrate using CMOS transistors. The wireless device 100 also includes the LNA 116, which may include one or more power amplifiers configured to amplify received signals in a similar or different manner as power amplifier(s) of the PA module 112.

The wireless device 100 also includes the switching circuit 118, which is configured to switch between different bands and/or modes. For example, the switching circuit 118 may be configured to couple the LNA 116 to the antenna 120 in a receive mode of operation and to decouple the LNA 116 from the antenna 120 in a transmit mode of operation. Similarly, the PA module 112 is coupled to the antenna 120 such that signals provided to the antenna 120 from the PA module 112 in the transmit mode of operation bypass the receive path (and switching circuit 118) of the wireless device 100. In some examples, the switching circuit 118 may be configured to couple and/or decouple the LNA 116 and/or PA module 112 to one or more of several antennas, which may include the antenna 120.

Accordingly, in certain embodiments the antenna 120 can both receive signals that are provided to the transceiver 108 via the switching circuit 118 and the LNA 116 and also transmit signals from the wireless device 100 via the transceiver 108, the PA module 112, and the coupler 114. However, in other examples multiple antennas can be used for different modes of operation.

The power-management system 110 is connected to the transceiver 108 and is configured to manage the power for the operation of the wireless device 100. The power-management system 110 can also control the operation of the wireless device 100, such as by controlling components of power amplifier(s) of the PA module 112 and/or LNA 116. The power-management system 110 can include, or can be connected to, a battery that supplies power for the various components of the wireless device 100. The power-management system 110 can further include one or more processors or controllers that can control the transmission of signals and can also configure components of the wireless device 100 based upon the frequency of the signals being transmitted or received, for example. In addition, the processor(s) or controller(s) of the power-management system 110 may provide control signals to actuate switches, tune components, or otherwise configure components of the wireless device 100, such as components of the PA module 112 and/or LNA 116, as discussed below. In at least one embodiment, the processor(s) or controller(s) of the power-management system 110 can also provide control signals to control the switching circuit 118 to operate in the transmit or receive mode.

In one embodiment, the baseband sub-system 106 is connected to the user interface 102 to process input and output of voice and/or data provided to and received from the user. The baseband sub-system 106 can also be connected to the memory and/or storage 104 which is configured to store data and/or instructions to control the operation of the wireless device, and/or to provide storage of information for the user.

The wireless device 100 also includes the coupler 114 having one or more coupler sections for measuring transmitted power signals from the PA module 112 and for providing one or more coupled signals to at least one sensor 122. In some examples, the coupler 114 is further configured to measure transmitted power signals from the LNA 116. In various examples, the wireless device 100 includes one or more couplers in addition to, or in lieu of, the coupler 114 to measure transmitted power signals from the LNA 116.

The at least one sensor 122 can in turn send information to the transceiver 108, power-management system 110, and/or directly to the PA module 112 and/or LNA 116 as feedback for making adjustments to regulate the power level of the PA module 112 and/or LNA 116. In this way the coupler 114 can be used to boost/decrease the power of a transmission signal having a relatively low/high power. It will be appreciated, however, that the coupler 114 can be used in a variety of other implementations.

For example, in certain embodiments in which the wireless device 100 is a mobile phone having a time division multiple access (TDMA) architecture, the coupler 114 can advantageously manage the amplification of an RF transmitted power signal from the PA module 112 and/or LNA 116. In a mobile phone having a TDMA architecture, such as those found in GSM, CDMA, and W-CDMA systems, the PA module 112 can be used to shift power envelopes up and down within prescribed limits of power versus time. For instance, a particular mobile phone can be assigned a transmission time slot for a particular frequency channel. In this case the PA module 112 and/or LNA 116 can be employed to aid in regulating the power level one or more RF power signals over time, so as to prevent signal interference from transmission during an assigned receive time slot and to reduce power consumption. In such systems, the coupler 114 can be used to measure the power of a power-amplifier output signal to aid in controlling the PA module 112 and/or LNA 116, as discussed above. The implementations shown in FIG. 1 is exemplary and non-limiting. For example, the implementation of FIG. 1 illustrates the coupler 114 being used in conjunction with a transmission of an RF signal, however, it will be appreciated that various examples of the coupler 114 discussed herein can also be used with received RF signals or other signals as well.

As discussed above, the PA module 112 and/or LNA 116 may each include one or more power amplifiers. For example, at least the PA module 112 may include one or more push-pull power amplifiers configured to receive an RF input signal, amplify the RF input signal, and provide an amplified RF output signal to an output.

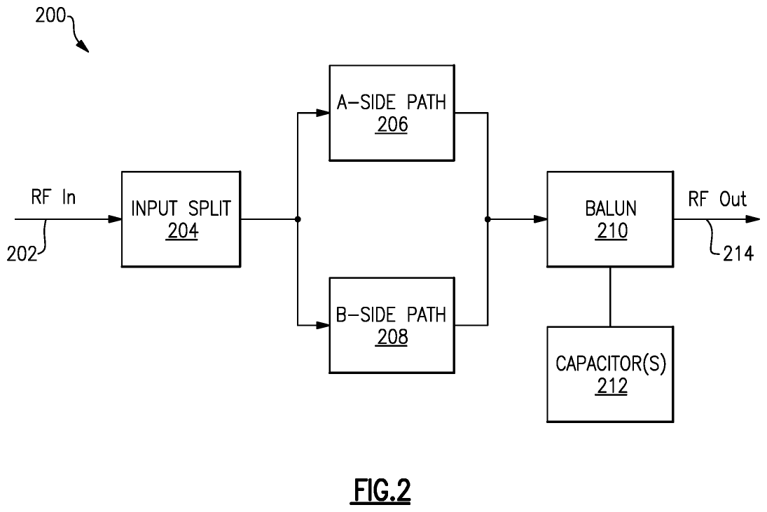

FIG. 2 illustrates a block diagram of a power amplifier 200 according to an example. In various examples, the power amplifier 200 may include a push-pull power amplifier. The power amplifier 200 includes an RF-signal input 202, an input split 204, an A-side signal path 206, a B-side signal path 208, a balun 210, one or more capacitors 212 (“capacitor 212”), and an RF-signal output 214.

The RF-signal input 202 is coupled to the input split 204, and is configured to be coupled to a source of an RF signal, such as the transceiver 108. The input split 204 is coupled to the RF-signal input 202, the A-side signal path 206, and the B-side signal path 208. The A-side signal path 206 is coupled to the input split 204 and to the balun 210. The B-side signal path 208 is coupled to the input split 204 and to the balun 210. The balun 210 is coupled to the A-side signal path 206, the B-side signal path 208, the capacitor 212, and to the RF-signal output 214. The capacitor 212 is coupled to the balun 210. The RF-signal output 214 is coupled to the balun 210, and is configured to be coupled to a component configured to receive an amplified RF signal, such as the coupler 114.

The input split 204 is configured to receive an input signal, split the input signal into two balanced signals, and provide the two balanced signals to the A-side signal path 206 and the B-side signal path 208. The signal paths 206, 208 are configured to transmit the balanced signals to the balun 210. The balun 210 is configured to convert the balanced signals to an unbalanced signal, and provide the unbalanced signal to the RF-signal output 214. The capacitor 212 is configured to improve a performance of the balun 210. For example, the capacitor 212 may mitigate or eliminate losses caused by a leakage inductance of the balun 210.

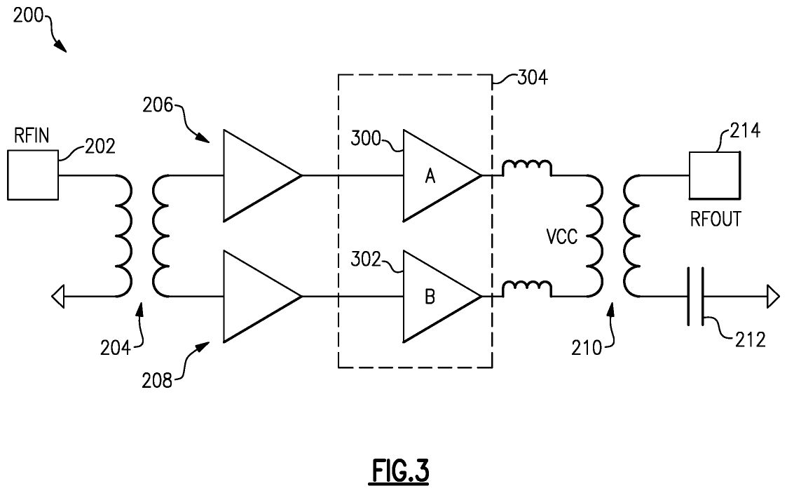

FIG. 3 illustrates a high-level schematic diagram of the power amplifier 200 according to an example. As illustrated, the input split 204 may include a transformer configured to transform an unbalanced RF-input signal into a balanced signal and provide the balanced signal to the signal paths 206, 208. The A-side signal path 206 includes a first driver 300 and the B-side signal path 208 includes a second driver 302, each configured to provide the balanced signals to the balun 210. The drivers 300, 302 are collectively identified as a final stage 304 of the power amplifier 200. The final stage 304 may alternately be referred to as an “output stage.” The balun 210 may include a transformer configured to transform the balanced signals into an unbalanced signal, and provide the balanced signal to the RF-signal output 214. The capacitor 212, as discussed above, may increase an efficiency of the power amplifier 200 by balancing the balun 210.

In various examples, a load line of the power amplifier 200 may be controlled by coupling a load modulator to the capacitor 212. The load modulator may enable parameters of the power amplifier 200, such as PAE, gain, PSAT, and so forth, to be controlled. The ability to control these parameters may advantageously enable the power amplifier 200 to exhibit desired characteristics for a particular set of operating conditions.

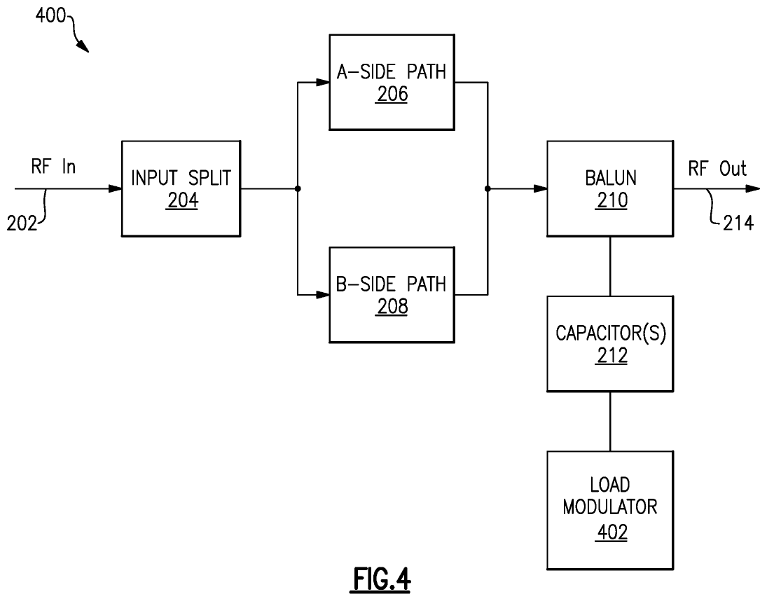

FIG. 4 illustrates a block diagram of a power amplifier 400 according to an example. The power amplifier 400 is similar to the power amplifier 200, and similar components are labeled accordingly. The power amplifier 400 includes the RF-signal input 202, the input split 204, the A-side signal path 206, the B-side signal path 208, the balun 210, the capacitor 212, and the RF-signal output 214. The power amplifier 400 also includes a load modulator 402. The load modulator 402 is coupled to the capacitor 212. The load modulator 402 may alternately be referred to as a “variable load,” a “controllable load,” a “variable resistance,” a “controllable resistance,” and so forth.

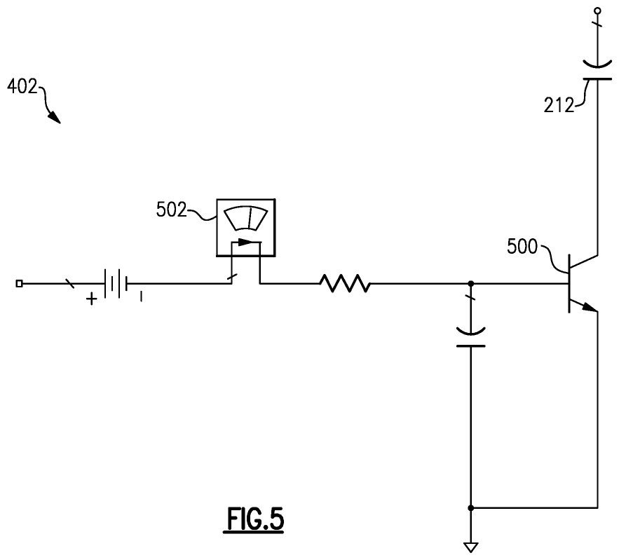

The load modulator 402 may provide a variable resistance to the capacitor 212. In one example, the load modulator 402 includes a switch (for example, a heterojunction bipolar transistor [HBT]) configured to operate as a variable resistor. For example, FIG. 5 illustrates a schematic diagram of the load modulator 402 coupled to the capacitor 212 according to an example. In this example, the load modulator 402 includes a switch 500 coupled in series between the capacitor 212 and a reference node (for example, a ground node). In some examples the switch 500 may be an npn HBT, although in other examples the switch 500 may be another type of switch, such as a BJT, MOSFET, and so forth. A state of the switch 500 may be controlled by varying a control signal provided by a control-signal source 502. The control-signal source 502 may provide the control signal to a control connection (for example, a base) of the switch 500. The control-signal source 502 may include, or be coupled to, at least one controller configured to control the control signal provided by the control-signal source 502. For example, the wireless device 100 may include at least one controller.

In various examples, a load line of the power amplifier 400 may be maximized by the control-signal source 502 fully opening the switch 500 (for example, by decreasing a magnitude of a voltage and/or current of the control signal) and thereby coupling the capacitor 212 to an open circuit. A load line of the power amplifier 400 may be minimized by the control-signal source 502 fully closing the switch 500 (for example, by increasing a magnitude of a voltage and/or current of the control signal) such that the switch 500 behaves as a resistor, which may be beneficial for modulated efficiency of a high peak-to-average-ratio waveform. A loss may be minimized at the highest load line, that is, where the control-signal source 502 fully opens the switch 500.

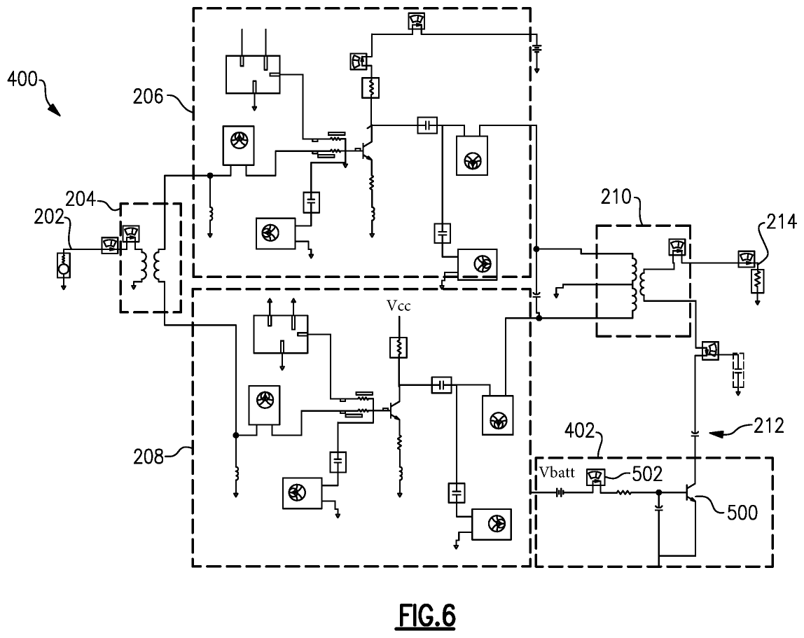

FIG. 6 illustrates a schematic diagram of the power amplifier 400 according to one example. The power amplifier 400 includes the RF-signal input 202, the input split 204, the A-side signal path 206, the B-side signal path 208, the balun 210, the capacitor 212, the RF-signal output 214, and the load modulator 402, which includes the switch 500 and the control-signal source 502. As discussed above, a control signal output by the control-signal source 502 to the switch 500 may be modulated to control various parameters of the power amplifier 400.

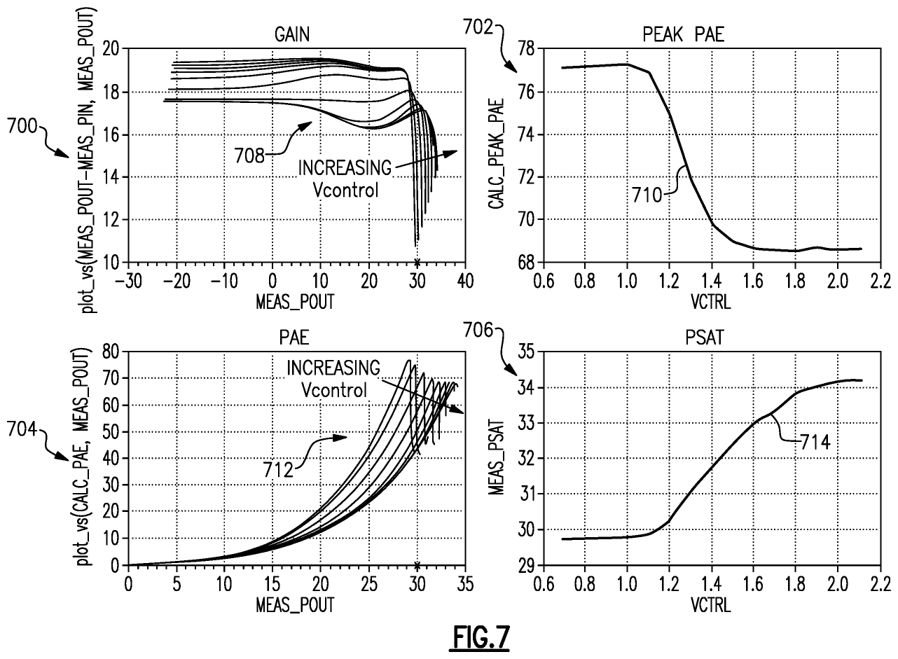

For example, FIG. 7 illustrates a first graph 700, a second graph 702, a third graph 704, and a fourth graph 706, depicting the effects of modulating the control signal provided by the control-signal source 502 according to an example. The first graph 700 includes a plurality of traces 708, where each trace corresponds to a respective value of the control signal provided by the control-signal source 502. The plurality of traces 708 indicate a gain of the power amplifier 400 as a function of output power. As indicated by the plurality of traces 708, for each value of the control signal, a gain may be approximately linear until the output power reaches a respective PSAT value, at which point the gain falls off significantly. Although decreasing the value of the control signal may increase a respective PSAT, the gain may generally be lower at most output-power values as compared to increasing the value of the control signal.

The second graph 702 includes a trace 710 indicating a peak PAE of the power amplifier 400 as a function of the value of the control signal provided by the control-signal source 502. As indicated by the trace 710, the peak PAE may decrease as the value of the control signal increases. Accordingly, the peak PAE may be maximized where a value of the control signal is minimized, which may be indicative of the switch 500 being in an open and non-conducting position.

The third graph 704 includes a plurality of traces 712, each corresponding to a respective value of the control signal. The plurality of traces 712 indicate a PAE of the power amplifier 400 as a function of output power. As indicated by the plurality of traces 712, a peak PAE may decrease as the value of the control signal increases. However, the peak PAE may correspond to a higher value of the output power as the control signal increases. Accordingly, although the highest PAE may be achieved by minimizing a value of the control signal, increasing the value of the control signal may enable higher PAE values for higher output-power values.

The fourth graph 706 includes a trace 714 indicating a PSAT of the power amplifier 400 as a function of the value of the control signal provided by the control-signal source 502. As indicated by the trace 714, a PSAT may increase as the value of the control signal increases. Accordingly, a tuning range of the power amplifier 400 may be broadened by increasing the value of the control signal and thereby increasing the PSAT. For example, as illustrated by the fourth graph 706, a tuning range of the power amplifier 400 may be increased by approximately 4 dB between a control-signal value of 1V and a control-signal value of 2V.

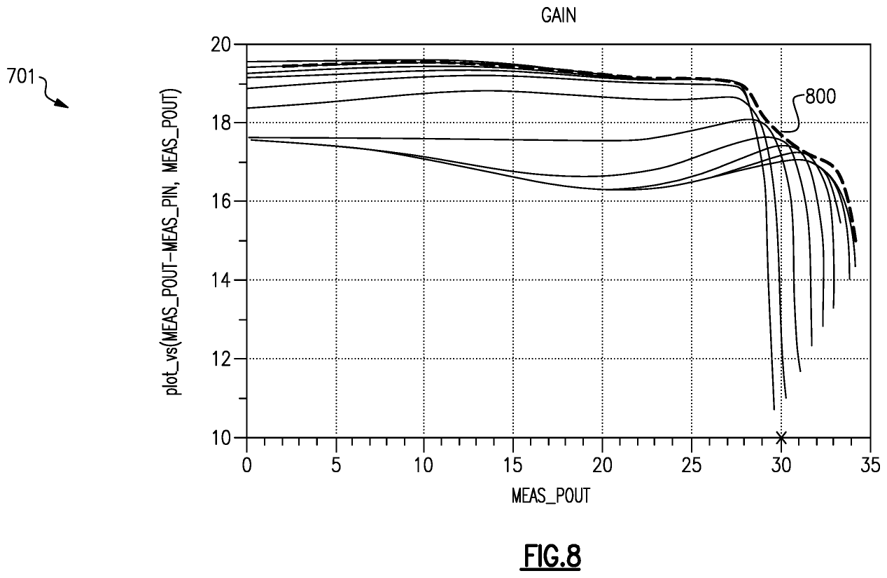

In some examples, it may be advantageous to vary a value of the control signal based on an output power provided by the power amplifier 400. As the output power nears the saturation point at PSAT, the control signal may be increased to increase the PSAT value. However, as discussed above, increasing the control signal may decrease a gain and PAE of the power amplifier 400. For example, FIG. 8 illustrates a first graph 701 including a trace 800 tracking a highest gain of the power amplifier 400 for a given value of the output power. As indicated by the trace 800, increasing the output power beyond the PSAT corresponding to the lowest value of the control signal may be achieved by increasing the value of the control signal. However, the gain may drop by a relatively large and uneven amount as the control signal is increased, thereby adversely impacting the AMAM performance of the power amplifier 400, as evidenced by the fact that the trace 800 is not perfectly linear (that is, horizontal). Accordingly, the AMAM response may be compressed at the top 4 dB of output power at least in part due to the inverse relationship between PSAT and gain as the control signal is modulated.

An AMAM response of example power amplifiers may be enhanced by adding a second stage. For example, the second stage may be a driver stage coupled to an input of a power amplifier. The driver stage may cause a composite gain of a power amplifier to increase as PSAT increases, such that the AMAM response is not adversely impacted by modulating the control signal.

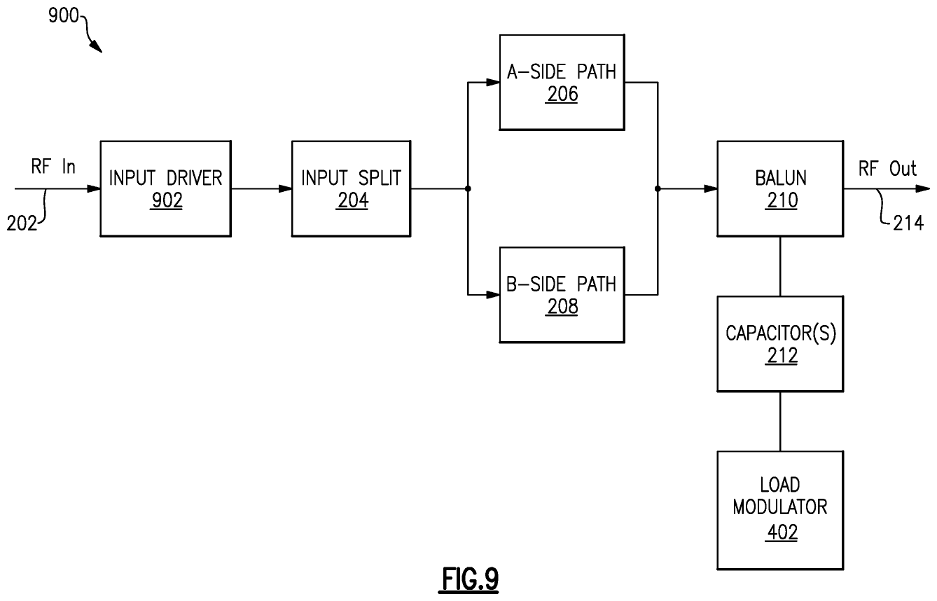

FIG. 9 illustrates a block diagram of a power amplifier 900 according to an example. The power amplifier 900 is similar to the power amplifier 400, and like components are labeled accordingly. The power amplifier 900 includes the RF-signal input 202, the input split 204, the A-side signal path 206, the B-side signal path 208, the balun 210, the capacitor 212, the RF-signal output 214, and the load modulator 402. The power amplifier 900 also includes an input driver 902. The input driver 902 is coupled to the RF-signal input 202, and is coupled to the input split 204.

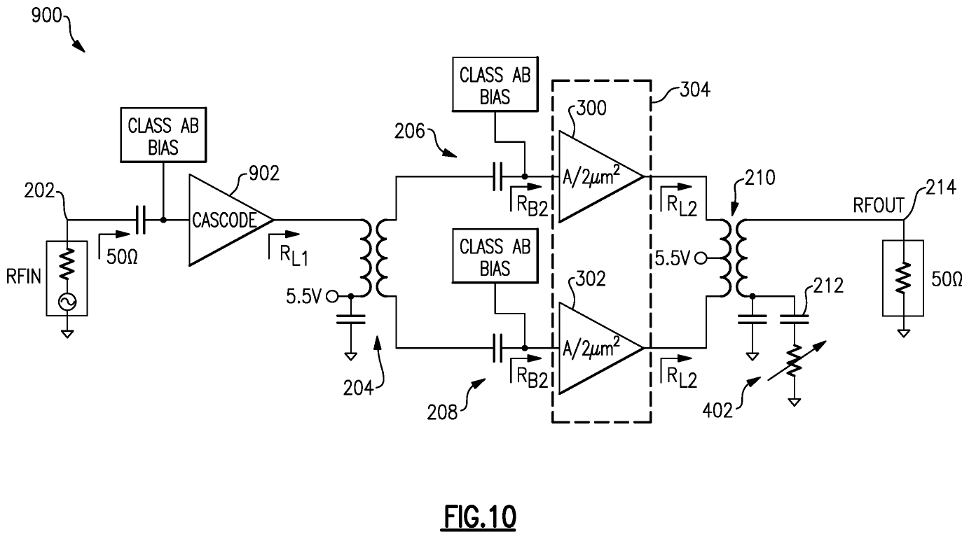

FIG. 10 illustrates a schematic diagram of the power amplifier 900 according to an example. As illustrated, the input driver 902 is configured to receive an input signal from the RF-signal input 202, and provide, at a collector of the input driver 902, an output signal to the input split 204. The input split 204 splits the input signal into balanced signals and provides the balanced signals to the respective bases of the drivers 300, 302 (that is, to the base of the final stage 304). The drivers 300, 302 output, at a respective collector of each of the drivers 300, 302 (that is, at a collector of the final stage 304), an output signal to the balun 210. The balun 210 provides an output signal to the RF-signal output 214. The capacitor 212 and load modulator 402 improve performance of the balun 210 as discussed above.

An interstage matching between the collector of the input driver 902 and the base of the final stage 304 may be adjusted such that the impedance of the collector of the input driver 902 increases as the PSAT of the power amplifier 900 increases. Increasing the impedance of the collector of the input driver 902 as PSAT increases may advantageously cause a composite gain of the power amplifier 900 to increase as PSAT increases.

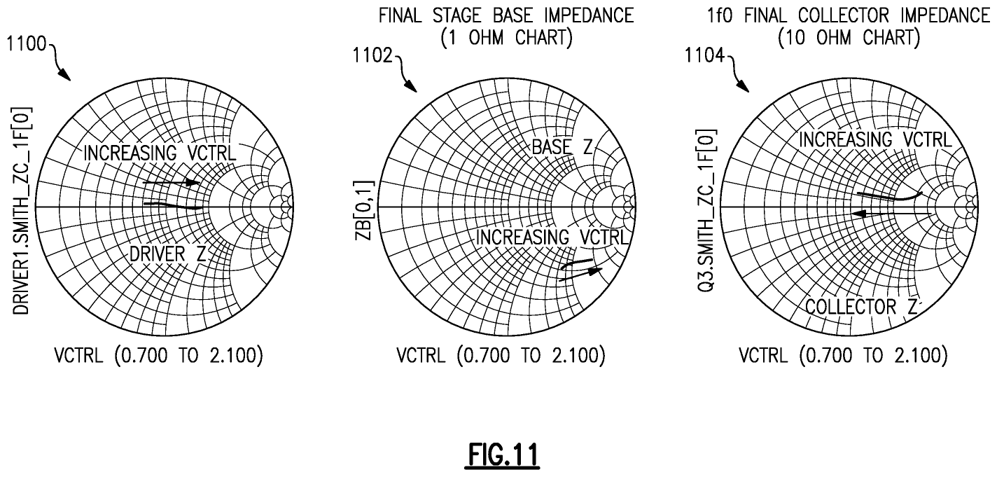

The interstage match between the input driver 902 and the final stage 304 may be selected such that the input driver 902 is out of phase with the final stage 304. To illustrate the foregoing, FIG. 11 includes a first Smith chart 1100, a second Smith chart 1102, and a third Smith chart 1104. The first Smith chart 1100 indicates an impedance of a collector of the driver stage 902 as a value of the control signal provided by the control-signal source 502 is increased. The second Smith chart 1102 indicates an impedance of a base of the final stage 304 as a value of the control signal provided by the control-signal source 502 is increased. The third Smith chart 1104 indicates an impedance of a collector of the final stage 304 as a value of the control signal provided by the control-signal source 502 is increased.

As indicated by the Smith charts 1100, 1104, the impedance of the collector of the input driver 902 increases as a function of the control signal provided by the control-signal source 502, and the impedance of the base of the final stage 304 decreases as a function of the control signal provided by the control-signal source 502. Consequently, varying the control signal enables both a gain and a PSAT of the power amplifier 900 to be simultaneously increased or decreased, which provides better AMAM performance.

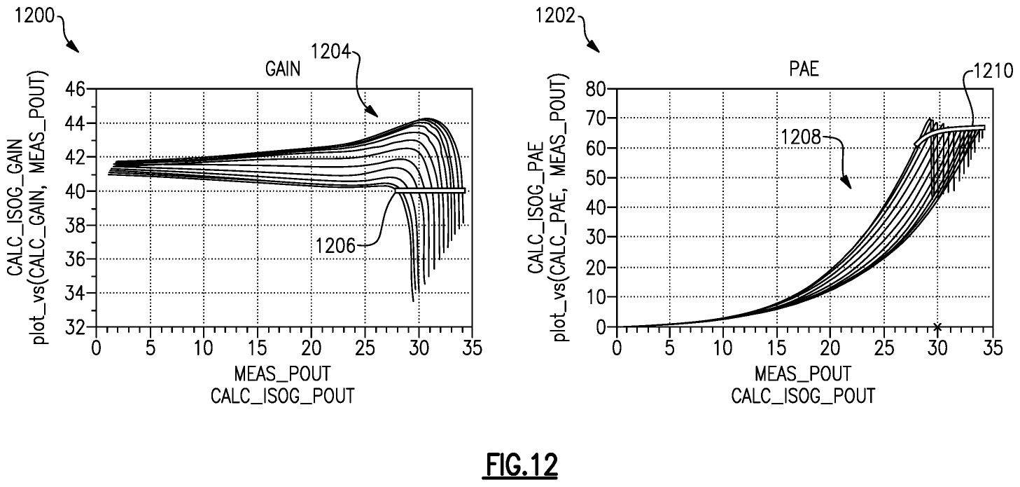

For example, FIG. 12 illustrates a first graph 1200 and a second graph 1202 indicative of respective performances of the power amplifier 900 at various control-signal values according to an example. The first graph 1200 illustrates a gain of the power amplifier 900 as a function of output power. The first graph 1200 includes a plurality of traces 1204, each corresponding to a respective value of the control signal provided by the control-signal source 502. Comparing the plurality of traces 1204 to the plurality of traces 708, the gain of the power amplifier 900 increases as the control signal provided by the control-signal source 502 is increased. A target-gain line 1206 indicates a gain as a function of output power that may be achieved, at a substantially constant value, by the control-signal source 502 modulating the control signal to a corresponding value as the magnitude of the control signal as an output power increases. The target-gain line 1206 indicates one example gain that may be achieved by the power amplifier 900, but different gains (for example, higher gains) may be achieved by the power amplifier 900. As indicated by the substantially horizontal nature of the target-gain line 1206, the power amplifier 900 exhibits considerably improved AMAM performance as compared to, for example, the AMAM performance illustrated by the trace 800.

The second graph 1202 indicates a PAE of the power amplifier 900 as a function of output power. The second graph 1202 includes a plurality of traces 1208, each corresponding to a respective value of the control signal provided by the control-signal source 502. A target-PAE line 1210 indicates a PAE as a function of output power that may be achieved at the control signal values corresponding to the target-gain line 1206. As illustrated by the target-PAE line 1210, the PAE increases as the control signal provided by the control-signal source 502 increases.

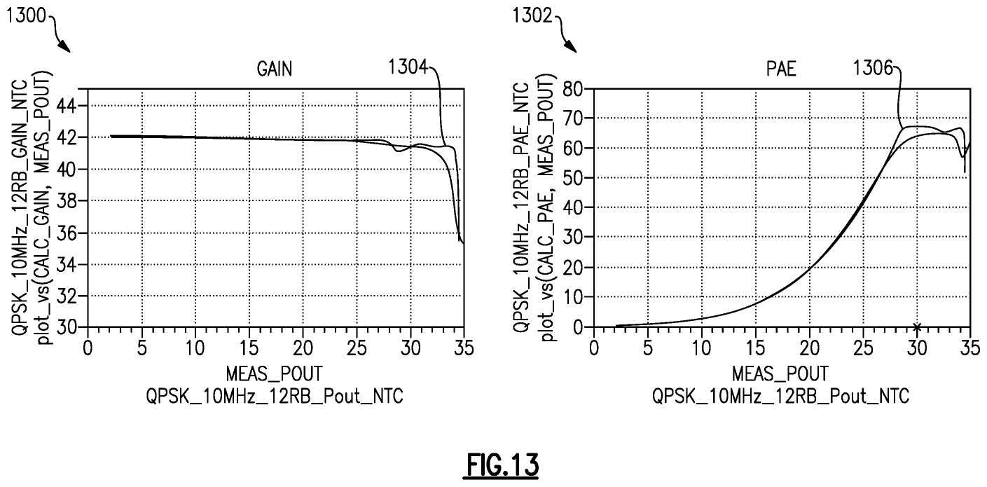

FIG. 13 illustrates a first graph 1300 and a second graph 1302 indicative of overall performance of the power amplifier 900 for a varied control signal according to an example. The first graph 1300 illustrates an overall gain of the power amplifier 900 that may be achieved by modulating the control signal as a function of output power. The first graph 1300 includes a trace 1304 indicating an output power of the power amplifier 900. As indicated by the trace 1304, the gain of the power amplifier 900 is substantially constant at high output-power values (for example, between approximately 30 dB and approximately 34 dB), advantageously exhibiting high AMAM performance.

The second graph 1302 illustrates an overall PAE of the power amplifier 900 that may be achieved by modulating the control signal as a function of output power. The second graph 1302 includes a trace 1306 indicating an output power of the power amplifier 900. As indicated by the trace 1306, the PAE of the power amplifier 900 is substantially constant at high output-power values (for example, between approximately 28 dB and approximately 34 dB) and is not substantially adversely impacted as the control signal provided by the control-signal source 502 is increased.

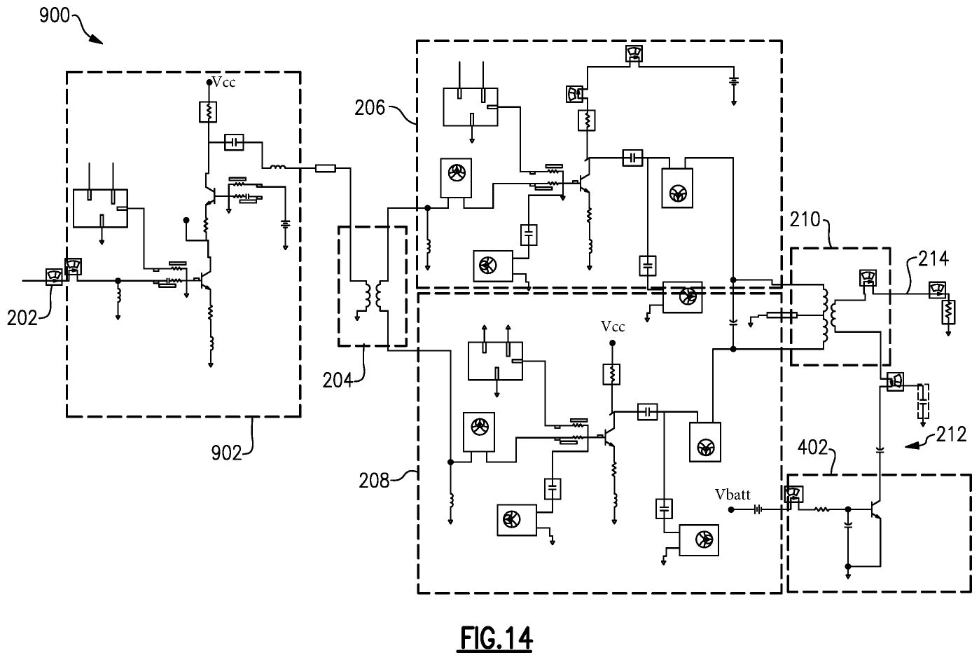

FIG. 14 illustrates a schematic diagram of the power amplifier 900 according to an example. The power amplifier 900 includes the RF-signal input 202, the input driver 902, the input split 204, the signal paths 206, 208, the balun 210, the capacitor 212, the RF-signal output 214, and the load modulator 402. Although certain configurations of the identified components are illustrated in FIG. 14, alternate configurations and implementations are within the scope of the disclosure. For example, although the input driver 902 is illustrated as including a cascode configuration, alternate configurations of the input driver 902 may be implemented, such as a common-emitter amplifier. Similarly, although the drivers 300, 302 are illustrated as including a common-emitter configuration, alternate configurations of the drivers 300, 302 may be implemented.

As discussed above, the wireless device 100 may include at least one controller. Various controllers, which may be implemented in the wireless device 100, may execute various operations discussed above. Using data stored in associated memory and/or storage, the controller(s) also execute one or more instructions stored on one or more non-transitory computer-readable media that may result in manipulated data. In some examples, the controller(s) may include one or more processors or other types of controllers. In one example, the controller(s) are or include at least one processor. In another example, the controller(s) perform at least a portion of the operations discussed above using an application-specific integrated circuit (ASIC) tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A power amplifier comprising:
an input to receive an input signal;
an output to provide an amplified output signal;
a balun coupled between the input and the output;
at least one capacitor coupled to the balun; and
a controllable load coupled to the at least one capacitor and being configured to present, with the at least one capacitor, a variable impedance to the balun.

2. The power amplifier of claim 1 wherein the controllable load includes a switch.

3. The power amplifier of claim 2 wherein the switch includes a heterojunction bipolar transistor.

4. The power amplifier of claim 1 further comprising:
an input split configured to transform the input signal to a balanced signal;
an input driver coupled between the input and the input split; and
an output driver coupled between the input driver and the balun.

5. The power amplifier of claim 4 further comprising an interstage match between the input driver and the output driver configured such that a collector impedance of the input driver is out-of-phase with a collector impedance of the output driver.

6. The power amplifier of claim 5 wherein increasing the controllable load increases a gain and a saturation power of the power amplifier.

7. The power amplifier of claim 6 wherein increasing the controllable load increases the collector impedance of the input driver and decreases a collector impedance of the output driver.

8. The power amplifier of claim 7 wherein the controllable load is a variable resistance.

9. The power amplifier of claim 4 wherein the input driver includes a cascode amplifier.

10. The power amplifier of claim 4 wherein the input driver includes a common-emitter amplifier.

11. The power amplifier of claim 4 wherein the output driver includes a common-emitter amplifier.

12. The power amplifier of claim 1 wherein the controllable load is a variable resistance.

13. A method of controlling a power amplifier comprising:
providing a power amplifier having a balun, at least one capacitor coupled to the balun, and a controllable load coupled to the at least one capacitor; and
varying the controllable load to improve an efficiency of the balun.

14. The method of claim 13 wherein the controllable load includes a switch, and wherein varying the controllable load includes varying a control signal provided to a control connection of the switch.

15. The method of claim 14 wherein the controllable load includes a variable resistor, and wherein varying the controllable load includes varying a resistance of the variable resistor.

16. The method of claim 14 wherein the power amplifier further includes an input driver and an output driver, the method further comprising implementing an interstage match between the input driver and the output driver such that a collector impedance of the input driver is out-of-phase with a collector impedance of the output driver.

17. The method of claim 16 wherein increasing the controllable load increases the collector impedance of the input driver and decreases a collector impedance of the output driver.

18. The method of claim 17 wherein increasing the controllable load includes increasing a resistance of the controllable load.

19. A power-amplifier system comprising:
an input to receive an input signal;
an output to provide an amplified output signal;
a balun coupled between the input and the output;
at least one capacitor coupled to the balun; and
means for varying a load coupled to the at least one capacitor.

20. The power-amplifier system of claim 19 further comprising means for simultaneously increasing a gain of the power-amplifier system and a saturated power point of the power-amplifier system.
